(19) United States
(12) Patent Application Publication
(10) Pub. No.: US 2012/0211866 A1
(43) Pub. Date: Aug. 23, 2012

(54) METAL-INSULATOR-METAL CAPACITOR AND A METHOD OF FABRICATING THE SAME

(75) Inventor: Chung-Wen Chao, (US)

(73) Assignee: SYSTEMS ON SILICON MANUFACTURING CO. PTE. LTD.

(21) Appl. No.: 13/030,111

(22) Filed: Feb. 17, 2011

(51) Int. Cl. H01L 29/92; H01L 21/02

(52) U.S. Cl. 257/532; 438/381; 257/E29.343; 257/E21.008

(57) ABSTRACT

A metal-insulator-metal (MIM) capacitor and a method of fabricating the same. The MIM capacitor is in a memory area of a wafer and comprises a top electrode formed from the same metal layer as a point contact to a via in the logic area of the wafer. The method of fabricating the MIM capacitor in a memory area of a wafer comprises forming a point contact to a via in a logic area of the wafer from the same metal layer as a top electrode of the MIM capacitor.

### TECHNICAL FIELD

The invention relates to a metal-insulator-metal capacitor and a method of fabricating the same.

### BACKGROUND

Integrated circuits (ICs) continue to increase in circuit density due to reduced sizes of circuit components made possible through the implementation of smaller and smaller circuit design rules. Consequently, to adhere to the smaller circuit design rules, new structures and new processing techniques need to be incorporated into the IC fabrication process.

A component that is increasingly incorporated into many IC designs is a metal-insulator-metal (MIM) capacitor, which typically comprises a stacked arrangement of materials that includes: top and bottom conductive electrodes and an intermediate insulator layer incorporating a dielectric material. Here, the top electrode is termed as the Capacitor Top Metal (CTM) and the bottom electrode is the Capacitor Bottom Metal (CBM). MIM capacitors are used e.g. in mixed signal (analog/digital) devices, RF (radio frequency) devices, and as decoupling capacitors for the filtering of high frequency signals and improved noise immunization.

FIGS. 1(a)-(d) are schematic cross-sectional diagrams, designated generally as reference numeral 100, illustrating the fabrication process of a typical prior art MIM capacitor.

A VIA_PH (photoresist) layer (not shown) is first deposited above an insulator layer 102. Thereafter, the photoresist layer is patterned to facilitate the etching of cavities within the insulator layer 102. A lining of glue (not shown), followed by tungsten, is deposited in the cavities. Chemical-mechanical polishing (CMP) is then carried out to planarize the insulator layer 102 such that tungsten plugs (vias) 104a/b/c are disposed within the insulator layer 102, as shown in FIG. 1(a).

In FIG. 1(b), a CBM layer 106 (M5 layer) is deposited above the insulator layer 102. An MIM insulator layer 108 is in turn deposited above the CBM layer 106. A CTM layer 110 is then deposited above the MIM insulator layer 108.

In FIG. 1(c), the CTM layer 110 and the MIM insulator layer 108 are etched such that only a portion of the CTM layer 110 and a portion if the MIM insulator layer 108 remains above the tungsten plugs 104a/b. The portion of the MIM insulator layer above the tungsten plugs 104a/b serve as the dielectric layer of the MIM capacitor.

In FIG. 1(d), the CBM layer 106 is etched such that a discontinuous CBM layer 106 is formed above the tungsten plugs 104a/b/c. The structure 112, comprising the CTM 110, dielectric layer 108 and CBM 106a, acts as the MIM capacitor.

With reference to FIG. 1, a point contact 105 to a via in a logic area of a wafer is formed from the same metal layer 106 as the bottom electrode 106a of the MIM. The formation of the relatively more critical structures (bottom electrode 106a and point contact 105) is influenced by the formation of the relatively less critical top electrode 110.

As design rules become tighter, one of the challenges in the fabrication of MIM capacitors is CTM over etching, which results in a thinner insulator remaining before CBM processing. Consequently, due to CTM etching damage, there may be defects such as CBM pits. MIM capacitor breakdown and leakage may also occur due to CTM lateral over etching.

In order to mitigate the consequences of CTM over etching, additional steps need to be implemented. Preventive actions such as extra N₂O treatment and/or formation of an extra CAP oxide are needed to prevent capacitor breakdown and leakage. Extra monitoring of the insulator oxide thickness for pits defect is also needed.

Another challenge in the fabrication of MIM capacitors is CTM under etching, which results in a thicker insulator remaining before CBM processing. Consequently, CBM bridging can occur. To mitigate CBM bridging, CBM etching time can be increased, but this can lead to over etching of the photoresist and critical dimension (CD) bias. The CBM may also suffer from poor critical dimension (CD) uniformity which may lead to a high rework rate. CBM peeling may also occur as the SiN insulator influences CBM photo surface reflectivity.

In order to mitigate the consequences of CTM under etching, additional steps need to be implemented. For example, to prevent peeling of the CBM, both bottom and top organic anti-reflective coatings (ARC) are used. This is in contrast to normal metal layers which use one bottom or one top organic ARC only. Special control is needed over the CBM etching tools, e.g. using golden tools and performing enhanced offline monitoring of photoresist and metal etching rate selectivity.

A need therefore exists to provide a metal-insulator-metal capacitor and a method of fabricating the same that seeks to address at least one of the abovementioned problems.

### SUMMARY

According to a first aspect of the present invention, there is provided a method of fabricating a metal-insulator-metal (MIM) capacitor in a memory area of a wafer comprising: forming a point contact to a via in a logic area of the wafer from the same metal layer as a top electrode of the MIM capacitor.

The method may comprise the steps of: forming a first metal layer; and patterning the first metal layer such that the patterned first metal layer covers portions of the one or more vias for the memory area for forming a bottom electrode of the MIM capacitor.

The method may further comprise the steps of: forming an insulator layer over the bottom electrode of the MIM capacitor; and fabricating the via in the logic area using a photo lithography process.

The method may further comprise the step of patterning the insulator layer to form a dielectric layer of the MIM capacitor.

The method may further comprise the step forming the point contact to the via in the logic area from a second metal layer formed over the dielectric layer of the MIM capacitor.

The first metal layer may comprise one or more of a group consisting of titanium nitride (TiN), aluminium and copper.

The second metal layer may comprise one or more of a group consisting of titanium nitride (TiN), aluminium and copper.

The dielectric layer of the MIM capacitor may comprise one or more of a group consisting of silicon nitride, resist protect oxide (RPO), plasma-enhanced undoped silicated glass (PEUSG) and Ta₂O₅.

According to a second aspect of the present invention, there is provided a metal-insulator-metal (MIM) capacitor in a memory area of a wafer, comprising: a top electrode formed from the same metal layer as a point contact to a via in the logic area of the wafer.

The MIM capacitor may further comprise a bottom electrode of the MIM capacitor formed from a patterned first metal layer; wherein the patterned first metal layer covers portions of the one or more vias for the memory area.

The MIM capacitor may further comprise a dielectric layer formed from a patterned insulator layer; wherein the patterned insulator layer is disposed above the bottom electrode of the MIM capacitor.

The point contact to the via in the logic area of the wafer may be formed from a second metal layer formed over the dielectric layer of the MIM capacitor.

The patterned first metal layer may comprise one or more of a group consisting of titanium nitride (TiN), aluminium and copper.

The patterned second metal layer may comprise one or more of a group consisting of titanium nitride (TiN), aluminium and copper.

The dielectric layer of the MIM capacitor may comprise one or more of a group consisting of silicon nitride, resist protect oxide (RPO), plasma-enhanced undoped silicated glass (PEUSG) and Ta₂O₅.

### BRIEF DESCRIPTION OF THE DRAWINGS

Example embodiments of the invention will be better understood and readily apparent to one of ordinary skill in the art from the following written description, by way of example only, and in conjunction with the drawings, in which:

FIGS. 1(a)-(d) are schematic cross-sectional diagrams illustrating the fabrication process of a typical prior art MIM capacitor.

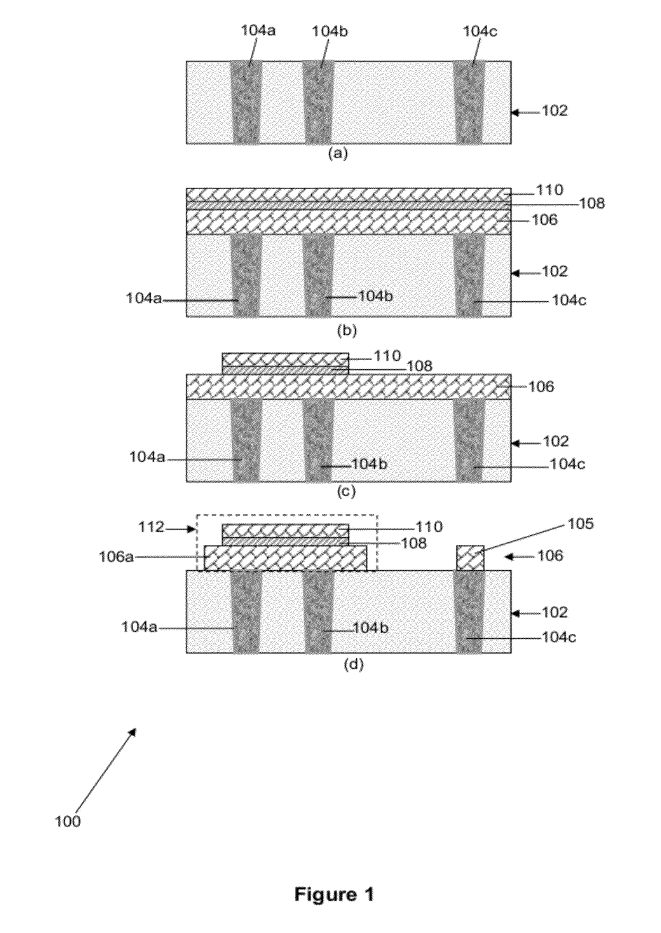

FIGS. 2(a)-(d) are schematic cross-sectional diagrams illustrating the fabrication process of an MIM capacitor, according to an embodiment of the present invention.

### DETAILED DESCRIPTION OF ILLUSTRATIVE EMBODIMENTS

Currently, in the fabrication of metal-insulator-metal (MIM) capacitors, the non-critical top electrode influences the critical bottom electrode and a point contact to a via in a logic area of a wafer to a large extent. The top electrode adheres to a loose design rule (e.g. >4.0 μm) while the bottom electrode layer adheres to a tighter design rule (e.g. 0.18 μm).

In embodiments of the present invention, a point contact to a via in a logic area of a wafer is formed from the same metal layer as a top electrode of a MIM capacitor. The point contact and the top electrode of the MIM capacitor are preferably formed at top metal-1 or top metal-2 layer and can be made of TiN (titanium nitride), AlCu, Cu, TiN/AlCu or TiN/AlCu/TiN. In an example embodiment, the thickness of the point contact and the top electrode is in the range of 1000-2000 Å and is fabricated using 0.11 μm technology comprising AlCu 1000-2000 Å and TiN 600-800 Å. The bottom electrode layer can be made of TiN, AlCu, Cu, TiN/AlCu or TiN/AlCu/TiN. In an example embodiment, the thickness of the bottom electrode is in the range of 2000-4000 Å and is fabricated using 0.11 μm technology comprising TiN 200-300 Å, AlCu 2000-4000 Å and TiN 200-300 Å.

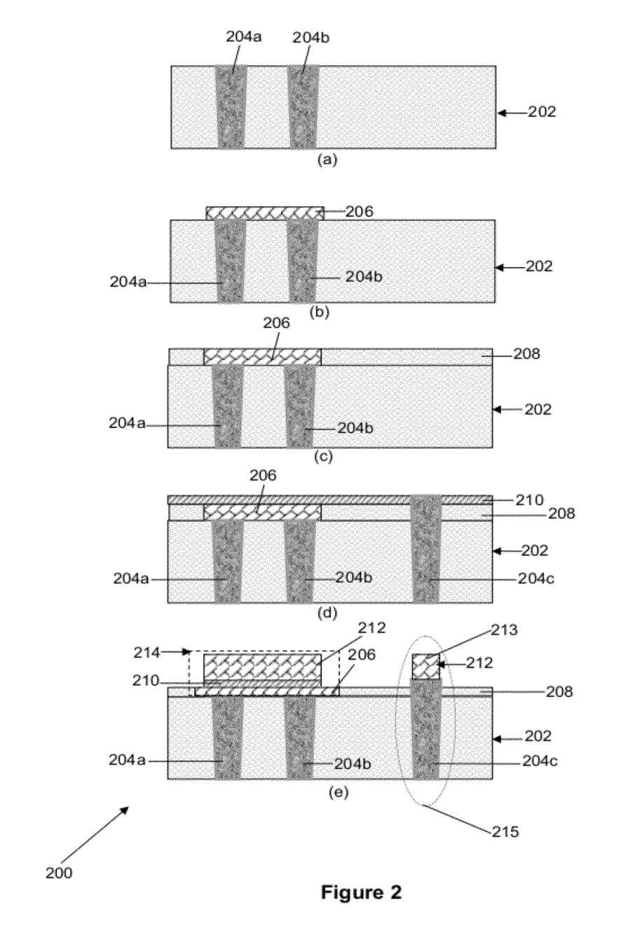

FIGS. 2(a)-(d) are schematic cross-sectional diagrams, designated generally as reference numeral 200, illustrating the fabrication process of an MIM capacitor, according to an embodiment of the present invention.

A VIA_PH_MIM (photoresist) layer (not shown) is first deposited above an insulator layer 202. The insulator layer 202 is an Inter Metal Dielectric, and can be made of suitable oxides such as silicon oxi-nitride (SiON), high density plasma fluorinated silicated glass (HDP_FSG), high density plasma undoped silicated glass (HDP_USG), plasma-enhanced fluorinated silicated glass (PEFSG), plasma-enhanced undoped silicated glass (PEUSG), sub-atmospheric pressure chemical vapour deposition (SACVD), spin on glass (SOG) and resist protect oxide (RPO), and composites thereof. In this example embodiment, the thickness of the insulator layer 202 is in the range of 4000-6000 Å and can be fabricated using 0.11 μm technology comprising HDP_FSG 2500-3500 Å, PEUSG 1500-2500 Å, SiON 250-350 Å and RPO 600-700 Å.

Thereafter, the photoresist layer is patterned to facilitate the etching of cavities within the insulator layer 202. A lining of glue (not shown), followed by tungsten, is deposited in the cavities. Chemical-mechanical polishing (CMP) is then carried out to planarize the insulator layer 202 such that tungsten plugs (vias) 204a/b are disposed within the insulator layer 202, as shown in FIG. 2(a).

In FIG. 2(b), a first metal layer 206 is deposited above the insulator layer 202. Suitable photolithography is carried out to etch the first metal layer 206 such that only a portion of the metal layer 206 remains above the tungsten plugs 204a/b. The portion of the metal layer 206 acts as the bottom electrode of the Metal-Insulator-Metal (MIM) capacitor.

A cap oxide 208 is deposited above the insulator layer 202. The cap oxide 208 is planarized such that the bottom electrode 206 and cap oxide 208 are substantially flush with respect to each other, as shown in FIG. 2(c). The cap oxide 208 can be made of suitable oxides such as HDP_FSG, HDP_USG, PEFSG, PEUSG, SACVD, SOG and RPO, and composites thereof. The thickness of the cap oxide 208 is thus substantially the same as that of the bottom electrode 206.

A MIM insulator layer 210 is deposited above the cap oxide layer 208. The MIM insulator layer 210 preferably comprises silicon nitride (SiN). The insulator layer 210 can also be made of RPO, PEUSG and Ta₂O₅, and composites thereof. In this example embodiment, the thickness of the insulator layer 210 is in the range of 100-500 Å and can be fabricated using 0.11 μm technology comprising RPO 300-350 Å for a 1 fF MIM option or SiN 250-300 Å for a 2 fF MIM option.

A suitable photo lithography process is performed to fabricate a via in the logic area. For example, a VIA_PH_non-MIM (photoresist) layer (not shown) is deposited above the cap oxide layer 208. Thereafter, the photoresist layer is patterned to facilitate the etching of a cavity within the insulator 202, cap oxide 208 and MIM insulator 210 layers. A lining of glue (not shown), followed by tungsten, is deposited in the cavity. Chemical-mechanical polishing (CMP) is then carried out to planarize the MIM insulator layer 210 such that a via in the logic area (i.e. third tungsten plug 204c) is disposed within the insulator 202, cap oxide 208 and MIM insulator 210 layers, as shown in FIG. 2(d). The plugs (vias) 204a/b/c can also be made of Ti, TiN, TaN and Cu, and composites thereof. In this example embodiment, it can be fabricated using 0.11 μm technology comprising IMP_Ti 50-150 Å, CVD_TiN 25-75 Å and W_deposition 2500-3000 Å.

The MIM insulator layer 210 is selectively etched such that only a portion of the MIM insulator layer 210 remains over the bottom electrode 206. The portion of the MIM insulator layer above the bottom electrode 206 serves as the dielectric layer of the MIM capacitor. A second metal layer 212 (M5 layer) is deposited above the dielectric layer 210. The second metal layer 212 is selectively etched such that a discontinuous second metal layer 212 remains above the tungsten plugs 204a/b/c. The portion of the second metal layer 212 above the dielectric layer 210 and the tungsten plugs 204a/b acts as the top electrode of the Metal-Insulator-Metal (MIM) capacitor. The structure 214, preferably located at the memory area of the wafer, comprising the bottom electrode 206, dielectric 210 and top electrode 212, acts as the MIM capacitor. The logic area 215 of a wafer comprises the tungsten plug (via) 204c and a point contact 213 above the tungsten plug (via) 204c.

The example embodiments described provide a method of fabricating an MIM capacitor comprising forming a point contact to a via in a logic area of the wafer from the same metal layer as a top electrode of the MIM capacitor.

It will be appreciated by a person skilled in the art that numerous variations and/or modifications may be made to the present invention as shown in the embodiments without departing from a spirit or scope of the invention as broadly described. The embodiments are, therefore, to be considered in all respects to be illustrative and not restrictive.

What is claimed:

1. A method of fabricating a metal-insulator-metal (MIM) capacitor in a memory area of a wafer comprising forming a point contact to a via in a logic area of the wafer from the same metal layer as a top electrode of the MIM capacitor.

2. The method as claimed in claim 1, comprising the steps of:
forming a first metal layer; and
patterning the first metal layer such that the patterned first metal layer covers portions of the one or more vias for the memory area for forming a bottom electrode of the MIM capacitor.

3. The method as claimed in claim 2, further comprising the steps of:
forming an insulator layer over the bottom electrode of the MIM capacitor; and fabricating the via in the logic area using a photo lithography process.

4. The method as claimed in claim 3, further comprising patterning the insulator layer to form a dielectric layer of the MIM capacitor.

5. The method as claimed in claim 4, further comprising forming the point contact to the via in the logic area from a second metal layer formed over the dielectric layer of the MIM capacitor.

6. The method as claimed in claim 2, wherein the first metal layer comprises one or more of a group consisting of titanium nitride (TiN), aluminium and copper.

7. The method as claimed in claim 5, wherein the second metal layer comprises one or more of a group consisting of titanium nitride (TiN), aluminium and copper.

8. The method as claimed in claim 4, wherein the dielectric layer of the MIM capacitor comprises one or more of a group consisting of silicon nitride, resist protect oxide (RPO), plasma-enhanced undoped silicated glass (PEUSG) and Ta₂O₅.

9. A metal-insulator-metal (MIM) capacitor in a memory area of a wafer, comprising: a top electrode formed from the same metal layer as a point contact to a via in the logic area of the wafer.

10. The MIM capacitor as claimed in claim 9, further comprising a bottom electrode of the MIM capacitor formed from a patterned first metal layer; wherein the patterned first metal layer covers portions of the one or more vias for the memory area.

11. The MIM capacitor as claimed in claim 10, further comprising a dielectric layer formed from a patterned insulator layer; wherein the patterned insulator layer is disposed above the bottom electrode of the MIM capacitor.

12. The MIM capacitor as claimed in claim 11, wherein the point contact to the via in the logic area of the wafer is formed from a second metal layer formed over the dielectric layer of the MIM capacitor.

13. The MIM capacitor as claimed in claim 10, wherein the patterned first metal layer comprises one or more of a group consisting of titanium nitride (TiN), aluminium and copper.

14. The MIM capacitor as claimed claim 12, wherein the patterned second metal layer comprises one or more of a group consisting of titanium nitride (TiN), aluminium and copper.

15. The MIM capacitor as claimed in claim 11, wherein the dielectric layer of the MIM capacitor comprises one or more of a group consisting of silicon nitride, resist protect oxide (RPO), plasma-enhanced undoped silicated glass (PEUSG) and Ta₂O₅.
